(19) United States
(12) Patent Application Publication
(10) Pub. No.: US 2023/0156965 A1
(43) Pub. Date: May 18, 2023

(54) HEAT-DISSIPATING STRUCTURE AND ELECTRONIC DEVICE COMPRISING THE HEAT-DISSIPATING STRUCTURE

(71) Applicant: SAMSUNG ELECTRONICS CO., LTD., Suwon-si (KR)

(72) Inventors: Haein CHUNG, Suwon-si (KR); Kyungha KOO, Suwon-si (KR); Dongku KANG, Suwon-si (KR); Kangsik KIM, Suwon-si (KR); Wonmin KIM, Suwon-si (KR); Jihong KIM, Suwon-si (KR); Chihwan JEONG, Suwon-si (KR)

(21) Appl. No.: 18/099,522

(22) Filed: Jan. 20, 2023

Related U.S. Application Data
(63) Continuation of application No. PCT/KR2021/009379, filed on Jul. 21, 2021.

(30) Foreign Application Priority Data
Jul. 21, 2020 (KR) 10-2020-0090629

(51) Int. Cl. H05K 7/20; H04M 1/02

(52) U.S. Cl. CPC H05K 7/20336; H04M 1/0283

(57) ABSTRACT

Disclosed is a heat-dissipating structure comprising: a case including: a first body and a second body spaced apart from each other; a wick disposed in a space between the first body and the second body, the wick including a plurality of wires arranged in a first direction and in a second direction intersecting the first direction, and having a working fluid passage formed along at least one opening formed between the plurality of wires; and a channel formed between the first body and the wick and in which the working fluid is moved through the at least one opening according to a change in state of the working fluid.

### CROSS REFERENCE TO RELATED APPLICATIONS

This application is a continuation of International Application No. PCT/KR2021/009379 designating the United States, filed on Jul. 21, 2021, in the Korean Intellectual Property Receiving Office and claiming priority to Korean Patent Application No. 10-2020-0090629, filed on Jul. 21, 2020, in the Korean Intellectual Property Office, the disclosures of which are incorporated by reference herein in their entireties.

### BACKGROUND

### Field

The disclosure relates to a heat-dissipating structure and an electronic device including the heat-dissipating structure.

### Description of Related Art

An electronic device (e.g., a smartphone) may include electronic components (e.g., a CPU) for performing various functions. Such electronic components may operate to execute a function (e.g., video playback) of the electronic device, and may generate heat during the operation. In addition, when the electronic components generate excessive heat, the performance of the electronic device may be deteriorated. Accordingly, the electronic device may include a heat-dissipating structure (e.g., a vapor chamber and/or a heat-pipe) to dissipate (e.g., radiate to the outside) heat generated in the electronic components.

An electronic device may have a reduced size to increase aesthetic perfection or reduce the cost thereof, beyond convenient portability. Accordingly, the size of a component (e.g., a wick) of a heat-dissipating structure disposed in the electronic device is also required to be reduced.

In the heat-dissipating structure, the size (e.g., a diameter) of multiple wires, which are components of a wick, is reduced in order to reduce the size of the wick, and the size of an opening formed between the multiple wires is also reduced, so that an internal pressure of the wick may be increased. In this case, in the heat-dissipating structure, considering the characteristics (e.g., high density and viscosity) of a working fluid in the electronic device which consumes relatively low power, the internal pressure of the wick may be increased as the size of the opening is reduced. The increased internal pressure of the wick may act as an obstacle factor to the flow of the working fluid having the above characteristics.

### SUMMARY

Embodiments of the disclosure may provide a heat-dissipating structure which dissipates heat generated in electronic components (e.g., radiates to the outside) while reducing the size of a component (e.g., a wick) of the heat-dissipating structure included in an electronic device.

Embodiments of the disclosure may provide a heat-dissipating structure and an electronic device including the heat-dissipating structure, wherein the size of an opening of a wick is determined such that a working fluid passing through the wick of the heat-dissipating structure smoothly flows.

A heat-dissipating structure according to an example embodiment disclosed herein may include: a case including: a first body and a second body spaced apart from each other, a wick disposed in a space between the first body and the second body and including multiple wires disposed in a first direction and in a second direction intersecting the first direction, a passage of a working fluid, the passage being formed along at least one opening formed between the multiple wires, and a channel formed between the first body and the wick and configured to move the working fluid through the at least one opening according to a change in a state of the working fluid, wherein the at least one opening is configured such that a size thereof is determined based on an internal pressure of the wick and a flow resistance of the working fluid.

In addition, an electronic device according to an example embodiment disclosed herein may include: a housing, a printed circuit board disposed inside the housing and including an electronic component, and a heat-dissipating structure disposed adjacent to the electronic component, wherein the heat-dissipating structure includes: a case including: a first body and a second body spaced apart from each other wherein the second body is in contact with the electronic component, a wick disposed in a space between the first body and the second body and including multiple wires disposed in a first direction and in a second direction intersecting the first direction, a passage of a working fluid, the passage being formed along at least one opening formed between the multiple wires, and a channel formed between the first body and the wick and configured to move the working fluid through the at least one opening according to a change in a state of the working fluid, and the at least one opening is configured such that a size thereof is determined based on an internal pressure of the wick and a flow resistance of the working fluid.

In a heat-dissipating structure and an electronic device including the heat-dissipating structure according to various example embodiments disclosed herein, the size of an opening of a wick is determined such that a working fluid passing through the wick of the heat-dissipating structure smoothly flows, so that the size of the heat-dissipating structure and the size of the electronic device may be reduced in a state of maintaining a heat-dissipating effect (e.g., emission to the outside) of the heat-dissipating structure.

Various other effects directly or indirectly identified through this disclosure may be provided.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a front perspective view illustrating a front surface of an electronic device according to various embodiments;

FIG. 2 is a rear perspective view illustrating a rear surface of the electronic device of FIG. 1 according to various embodiments;

FIG. 3 is an exploded perspective view of the electronic device of FIG. 1 according to various embodiments;

FIG. 4 is a diagram illustrating a heat-dissipating structure disposed in an electronic device according to various embodiments;

FIG. 5A is a cross-sectional view illustrating a part of a heat-dissipating structure according to various embodiments;

FIG. 5B is a cross-sectional view illustrating a part of a heat-dissipating structure according to various embodiments;

FIG. 5C is a cross-sectional view illustrating a part of an electronic device according to various embodiments;

FIG. 6 is a diagram illustrating an example heat-dissipating structure according to various embodiments;

FIG. 7 is a diagram illustrating an example wick of a heat-dissipating structure according to various embodiments;

FIG. 8 is a graph illustrating a relationship between an internal pressure of a wick and a flow resistance of a working fluid according to the size of an opening of a heat-dissipating structure according to various embodiments;

FIG. 9 is a diagram illustrating a heat-dissipating structure disposed in an electronic device according to various embodiments; and

FIG. 10 is a diagram illustrating an example electronic device in a network environment according to various embodiments.

In relation to the description of the drawings, the same reference numerals may be assigned to the same or corresponding components.

### DETAILED DESCRIPTION

Hereinafter, various example embodiments of the disclosure are described with reference to the accompanying drawings. However, this is not intended to limit the disclosure to specific embodiments, and should be understood to include various modifications, equivalents, and/or alternatives to embodiments of the disclosure.

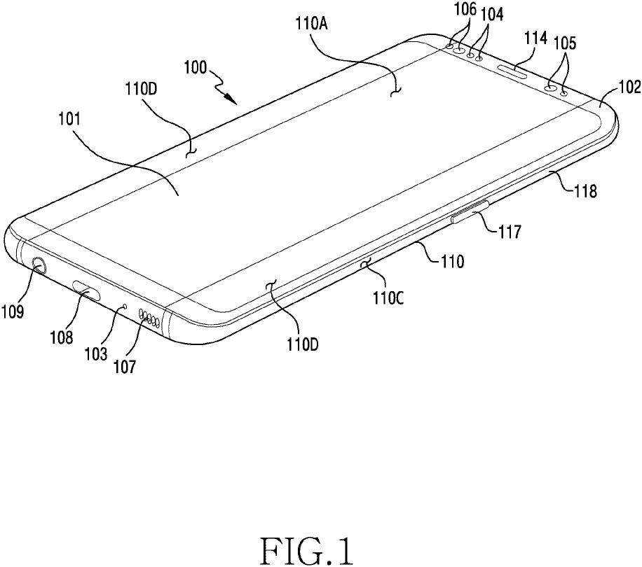

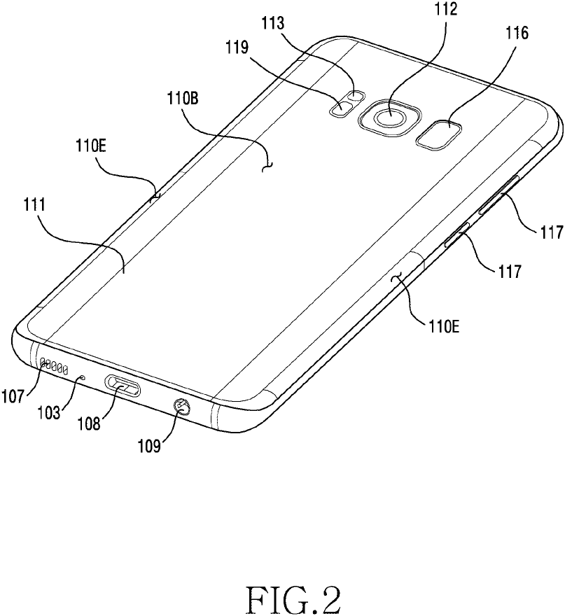

FIG. 1 is a front perspective view illustrating a front surface of an electronic device according to various embodiments. FIG. 2 is a rear perspective view illustrating a rear surface of the electronic device of FIG. 1 according to various embodiments.

Referring to FIGS. 1 and 2, an electronic device 100 according to an embodiment may include a housing 110 including a first surface (or a front surface) 110A, a second surface (or a rear surface) 110B, and a lateral surface 110C surrounding the space between the first surface 110A and the second surface 110B. In an embodiment (not illustrated), the housing may refer to a structure which forms a part of the first surface 110A, the second surface 110B, and the lateral surface 110C of FIG. 1. According to an embodiment, the first surface 110A may be configured by a front plate 102 (e.g., a polymer plate or a glass plate including various coating layers), at least a part of which is substantially transparent. The second surface 110B may be configured by a rear plate 111 which is substantially opaque. The rear plate 111 may be formed of, for example, coated or colored glass, ceramic, a polymer, or a metal (e.g., aluminum, stainless steel (STS), or magnesium), or a combination of two or more of the above materials. The lateral surface 110C may be configured by a lateral bezel structure (or a “lateral member”) 118 coupled to the front plate 102 and the rear plate 111 and including a metal and/or a polymer. In various embodiments, the rear plate 111 and the lateral bezel structure 118 may be integrally configured and may include the same material (e.g., a metal material such as aluminum).

In the illustrated embodiment, the front plate 102 may include, at opposite long edges of the front plate 102, two first areas 110D which are bent and seamlessly extend from the first surface 110A toward the rear plate 111. In the illustrated embodiment (see FIG. 2), the rear plate 111 may include, at opposite long edges thereof, two second areas 110E which are bent and seamlessly extend from the second surface 110B toward the front plate 102. In various embodiments, the front plate 102 (or the rear plate 111) may include only one of the first areas 110D (or the second areas 110E). In an embodiment, some of the first areas 110D and the second areas 110E may not be included. In the above embodiments, when viewed from a lateral side of the electronic device 100, the lateral bezel structure 118 may have a first thickness (or width) on the lateral surface where the first areas 110D or the second areas 110E are not included, and may have a second thickness, which is thinner than the first thickness, on the lateral surface where the first areas 110D or the second areas 110E are included.

According to an embodiment, the electronic device 100 may include at least one of a display 101, audio modules 103, 107, and 114, sensor modules 104, 116, and 119, camera modules 105 and 112, a key input device 117, a light-emitting element 106, and connector holes 108 and 109. In various embodiments, at least one (e.g., the key input device 117 or the light-emitting element 106) of the components may be omitted from the electronic device 100, or the electronic device 100 may additionally include other components.

For example, the display 101 may be visible through a significant part of the front plate 102. In various embodiments, at least a part of the display 101 may be visible through the front plate 102 forming the first areas 110D of the lateral surface 110C and the first surface 110A. In various embodiments, the edges of the display 101 may be configured to be substantially the same as the outer contour shape of the front plate 102 adjacent thereto. In an embodiment (not illustrated), the distance between the outer contour of the display 101 and the outer contour of the front plate 102 may be substantially constant in order to enlarge a visible or viewable area of the display 101.

In an embodiment (not illustrated), a recess or an opening is configured in a part of a screen display area of the display 101, and at least one of the audio module 114, the sensor module 104, the camera module 105, and the light-emitting element 106 aligned with the recess or the opening may be included. In an embodiment (not illustrated), at least one of the audio module 114, the sensor module 104, the camera module 105, a fingerprint sensor 116, and the light-emitting element 106 may be included on a rear surface of the screen display area of the display 101. In an embodiment (not illustrated), the display 101 may be coupled to or disposed adjacent to a touch-sensing circuit, a pressure sensor capable of measuring the intensity (pressure) of a touch, and/or a digitizer which detects a magnetic field-type stylus pen. In various embodiments, at least a part of the sensor modules 104 and 119 and/or at least a part of the key input device 117 may be disposed in the first areas 110D and/or the second areas 110E.

The audio modules 103, 107, and 114 may include a microphone hole 103 and speaker holes 107 and 114. The microphone hole 103 may include a microphone disposed therein so as to acquire external sound, and in various embodiments, multiple microphones may be disposed therein so as to detect the direction of sound. The speaker holes 107 and 114 may include an external speaker hole 107 and a phone call receiver hole 114. In various embodiments, the speaker holes 107 and 114 and the microphone hole 103 may be implemented as a single hole, or a speaker may be included without the speaker holes 107 and 114 (e.g., a piezo speaker).

The sensor modules 104, 116, and 119 may generate an electrical signal or a data value corresponding to an internal operating state of the electronic device 100 or an external environment state. The sensor modules 104, 116, and 119 may include, for example, a first sensor module 104 (e.g., a proximity sensor) and/or a second sensor module (not illustrated) (e.g., a fingerprint sensor) disposed on the first surface 110A of the housing 110, and/or a third sensor module 119 (e.g., an HRM sensor) and/or a fourth sensor module 116 (e.g., a fingerprint sensor) disposed on the second surface 110B of the housing 110. The fingerprint sensor may be disposed not only on the first surface 110A (e.g., the display 101) of the housing 110 but also on the second surface 110B. The electronic device 100 may further include a sensor module which is not illustrated, for example, at least one of a gesture sensor, a gyro sensor, an air pressure sensor, a magnetic sensor, an acceleration sensor, a grip sensor, a color sensor, an infrared (IR) sensor, a biometric sensor, a temperature sensor, a humidity sensor, or an illuminance sensor.

The camera modules 105 and 112 may include a first camera device 105 disposed on the first surface 110A of the electronic device 100, a second camera device 112 disposed on the second surface 110B, and/or a flash 113. The camera devices 105 and 112 may include one or multiple lenses, an image sensor, and/or an image signal processor. The flash 113 may include, for example, a light-emitting diode or a xenon lamp. In various embodiments, two or more lenses (an infrared camera, and wide-angle and telephoto lenses) and image sensors may be arranged on one surface of the electronic device 100.

The key input device 117 may be disposed on the lateral surface 110C of the housing 110. In an embodiment, the electronic device 100 may not include a part or all of the above-mentioned key input device 117, and the key input device 117, which is not included, may be implemented in another form, such as a soft key, on the display 101. In various embodiments, a key input device may include the sensor module 116 disposed on the second surface 110B of the housing 110.

For example, the light-emitting element 106 may be disposed on the first surface 110A of the housing 110. For example, the light-emitting element 106 may provide state information of the electronic device 100 in the form of light. In an embodiment, the light-emitting element 106 may provide a light source which is interlocked with, for example, an operation of the camera module 105. The light-emitting element 106 may include, for example, an LED, an IR LED, and a xenon lamp.

The connector holes 108 and 109 may include a first connector hole 108 capable of receiving a connector (e.g., a USB connector) for transmitting or receiving power and/or data to or from an external electronic device, and/or a second connector hole 109 (e.g., an earphone jack) capable of receiving a connector for transmitting or receiving an audio signal to or from an external electronic device.

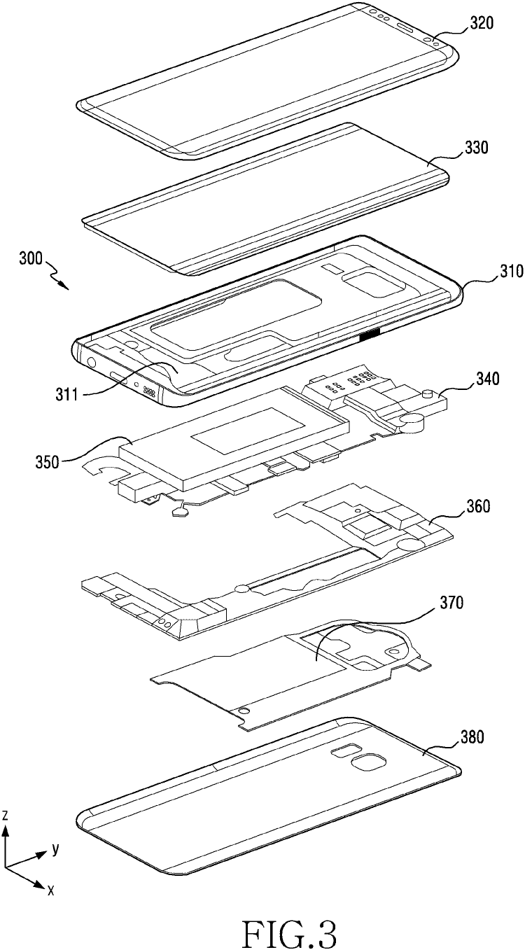

FIG. 3 is an exploded perspective view of the electronic device of FIG. 1 according to various embodiments.

Referring to FIG. 3, an electronic device 300 may include a lateral bezel structure 310, a first support member 311 (e.g., a bracket), a front plate 320, a display 330, a printed circuit board 340, a battery 350, a second support member 360 (e.g., a rear case), an antenna 370, and a rear plate 380. In various embodiments, at least one (e.g., the first support member 311 or the second support member 360) of the components may be omitted from the electronic device 300, or the electronic device 300 may additionally include other components. At least one of the components of the electronic device 300 may be the same as or similar to at least one of the components of the electronic device 100 of FIGS. 1 or 2, and a redundant description thereof is omitted below.

The first support member 311 may be disposed inside the electronic device 300 to be connected to the lateral bezel structure 310 or to be configured integrally with the lateral bezel structure 310. The first support member 311 may be made of, for example, a metal material and/or a non-metal (e.g., polymer) material. The first support member 311 may have one surface to which the display 330 is coupled, and the other surface to which the printed circuit board 340 is coupled. The printed circuit board 340 may include a processor, a memory, and/or an interface mounted thereon. The processor may include, for example, one or more of a central processing unit, an application processor, a graphic processing unit, an image signal processor, a sensor hub processor, or a communication processor.

The memory may include, for example, a volatile memory or a nonvolatile memory.

The interface may include, for example, a high-definition multimedia interface (HDMI), a universal serial bus (USB) interface, an SD card interface, and/or an audio interface. For example, the interface may electrically or physically connect the electronic device 300 to an external electronic device, and include a USB connector, an SD card/MMC connector, or an audio connector.

The battery 350 is a device for supplying power to at least one component of the electronic device 300 and may include, for example, a non-rechargeable primary cell, a rechargeable secondary cell, or a fuel cell. For example, at least a part of the battery 350 may be disposed substantially on the same plane as the printed circuit board 340. The battery 350 may be integrally disposed inside the electronic device 300 or may be disposed to be detachable from the electronic device 300.

The antenna 370 may be disposed between the rear plate 380 and the battery 350. The antenna 370 may include, for example, a near field communication (NFC) antenna, a wireless charging antenna, and/or a magnetic secure transmission (MST) antenna. For example, the antenna 370 may perform short-range communication with an external device or wirelessly transmit/receive power required for charging. In an embodiment, an antenna structure may be configured by a part of the lateral bezel structure 310 and/or the first support member 311 or a combination thereof.

Hereinafter, an example structure of an electronic device to which various embodiments related to the disclosure can be applied may be described with reference to FIGS. 1 to 3. However, FIGS. 1 to 3 merely illustrate, by way of non-limiting example, a structure of the electronic device, and the structure of the electronic device is not limited to the structure shown in FIGS. 1 to 3. For example, the electronic device may include at least one hinge structure to have a structure in which a housing divided into multiple areas is folded.

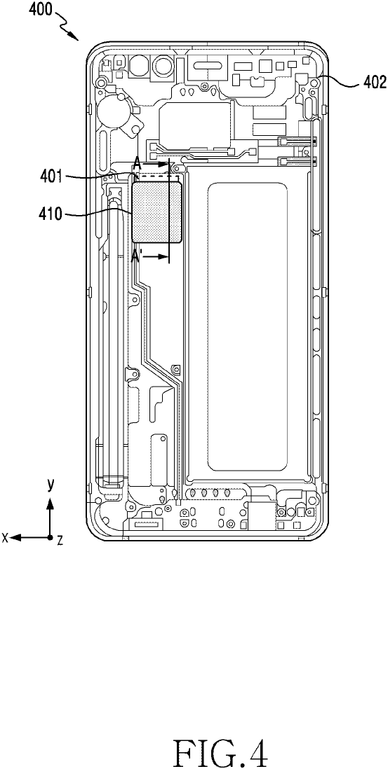

FIG. 4 is a diagram illustrating an example heat-dissipating structure disposed in an electronic device according to various embodiments. In an embodiment, FIG. 4 may be a view illustrating a state in which a rear plate (e.g., the rear plate 111 of FIG. 2 and the rear plate 380 of FIG. 3) and a second support member (e.g., the second support member 360 of FIG. 3) are removed from a rear surface (e.g., the electronic device in the state of FIG. 2) of an electronic device 400.

According to an embodiment, the electronic device 400 (e.g., the electronic device 300 of FIG. 3) may include an electronic component 401 (e.g., a CPU). In an embodiment, the electronic component 401 may operate to execute a function (e.g., video playback) of the electronic device 400, and heat may be generated according to the operation of the electronic component 401. In addition, the temperature of the inside (e.g., the inside of the housing 110 of FIG. 1) of the electronic device 400 may increase due to the heat generated from the electronic component 401. In an embodiment, the electronic component 401 may be disposed on a printed circuit board 402 (e.g., the printed circuit board 380 of FIG. 3).

According to an embodiment, the electronic device 400 may include a heat-dissipating structure 410 (e.g., a vapor chamber and/or a heat-pipe). In an embodiment, the heat-dissipating structure 410 may dissipate heat generated from the electronic component 401 to the inside (e.g., the inside of the housing 110 of FIG. 1) of the electronic device 400. In an embodiment, the heat-dissipating structure 410 may be configured to have a structure such that at least a part thereof is disposed adjacent to the surface of the electronic component 401. In an embodiment, the heat-dissipating structure 410 may cover at least a part of the electronic component 401. For example, when the heat-dissipating structure 410 is viewed from a specified direction (e.g., the z-axis direction), at least a part of the heat-dissipating structure 410 may overlap the electronic component 401.

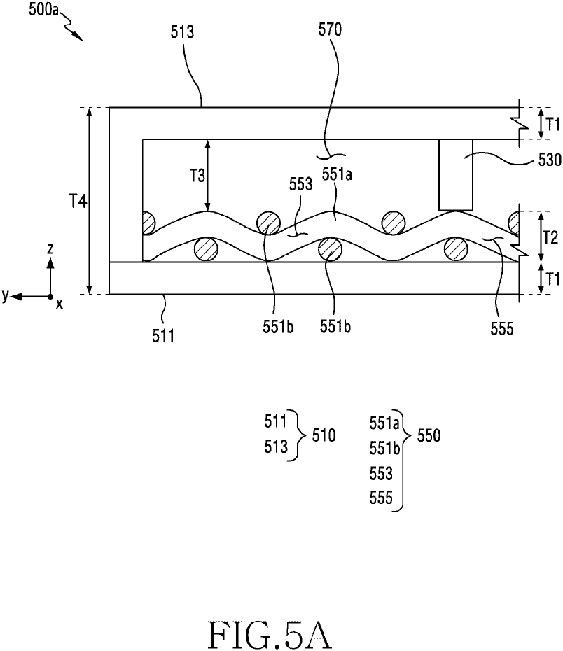

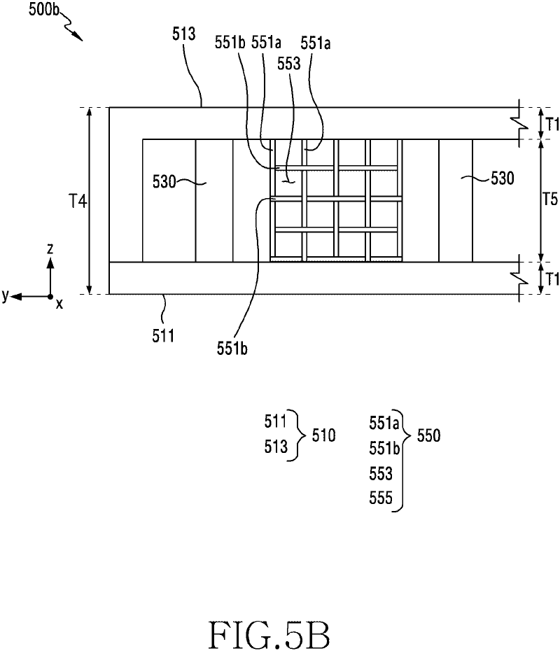

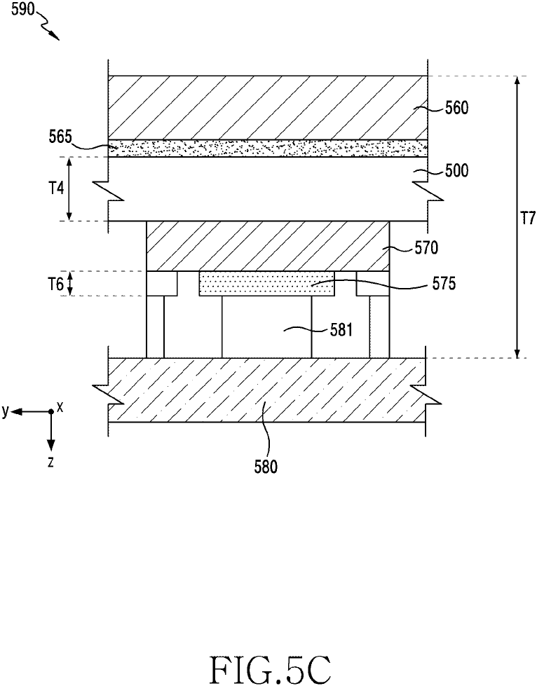

FIG. 5A is a cross-sectional view illustrating a part of a heat-dissipating structure according to various embodiments. In an embodiment, FIG. 5A may be a cross-sectional view taken along line A-A′ of FIG. 4 and viewed in the x-axis direction of FIG. 4. In an embodiment, FIG. 5A may be a view illustrating an example structure of a vapor chamber.

According to an embodiment, an electronic device (e.g., the electronic device 400 of FIG. 4) may include a heat-dissipating structure 500a (e.g., the heat-dissipating structure 410 of FIG. 4) identical to or similar to the shape of FIG. 5A in order to reduce the size (e.g., the length in the z-axis direction in FIG. 3) thereof in a state of maintaining a heat-dissipating effect (e.g., emission to the outside) of heat generated from an electronic component (e.g., the electronic component 401 of FIG. 4). In an embodiment, the heat-dissipating structure 500a may include at least one of a case 510, a support 530, a wick 550, and a channel 570. In an embodiment, the channel 570 may refer to a part of an inner space formed by the case 510, and may be dependently included in a component of the electronic device 400 according to whether the case 510 is included in the electronic device 400.

According to an embodiment, the case 510 may include at least one of a first body 511 and a second body 513 configured to absorb heat generated from the electronic component 401, transfer the heat to the inner space, and then radiate the heat to the inside (e.g., the inside of the housing 110 of FIG. 1) of the electronic device 400. In an embodiment, the first body 511 and the second body 513 may cause the size (e.g., a fourth thickness T4) of the heat-dissipating structure 500a to be determined according to a first thickness T1 (e.g., the length in the z-axis direction). According to an embodiment, the first thicknesses T1 of the first body 511 and/or the second body 513 are shown as being substantially the same, but may be different from each other. For example, the thickness of the first body 511 may be the first thickness T1, and the thickness of the second body 513 may be configured to have a thickness different from the first thickness T1. In an embodiment, the fourth thickness T4 related to the size of the heat-dissipating structure 500a may, for example, and without limitation, have a thickness of about 0.2 mm.

According to an embodiment, the first body 511 may absorb high-temperature heat from the electronic component 401 through a part of a first surface (e.g., the surface in the -z-axis direction) thereof. In an embodiment, the first body 511 may radiate the absorbed high-temperature heat through another part of the first surface. In an embodiment, the first body 511 may be configured to have a shape corresponding to the shape of the electronic component 401 in consideration of the first surface being in contact with the electronic component 401. In an embodiment, the first body 511 may be configured to have a shape which can receive the wick 550, in consideration of the wick 550 being disposed on a second surface (e.g., the surface in the z-axis direction) thereof.

According to an embodiment, the second body 513 may form an inner space of the case 510 such that at least one of the support 530, the wick 550, and the channel 570 is positioned inside the case 510. In an embodiment, both sides (e.g., one side in the y-axis direction and the other side in the -y-axis direction) of the second body 513 may protrude toward the second surface (e.g., the surface in the z-axis direction) of the first body 511. In an embodiment, the protruding both sides of the second body 513 may be at least partially coupled to the second surface of the first body 511. In an embodiment, when the high-temperature heat absorbed through the first body 511 is transferred to the inner space, the second body 513 may radiate the high-temperature heat toward an opposite direction (e.g., the z-axis direction) to a direction (e.g., the -z-axis direction) in which the first body 511 is positioned.

According to an embodiment, the case 510 may be made of a material of stainless steel. For example, and without limitation, the case 510 may be made of a stainless steel material of a 304 low (L) (or 316L) carbon steel material. When the stainless steel is joined at a high temperature, the stainless steel may be corroded due to the interference of oxide film formation by a chemical reaction of carbon (C) and chromium (Cr), and thus the case may be required to be made of a low-carbon steel material. According to an embodiment, the case 510 may include a material having thermal conductivity. For example, and without limitation, the case 510 may include at least one of graphite, a carbon nanotube, a natural regenerated material, or silicon.

According to an embodiment, each of the first body 511 and the second body 513 may have the first thickness T1 (e.g., the length in the z-axis direction). For example, each of the first body 511 and the second body 513 may have the first thickness T1 of about 30 µm after being etched. For another example, the first body 511 (or the second body 513) may have the first thickness T1 of about 30 µm as a sheet-shaped flat plate which is not etched.

According to an embodiment, in relation to the first body 511 and the second body 513, a part of the first body 511 in the z-axis direction and a part of the second body 513 in the -z-axis direction (e.g., both sides protruding in the z-axis direction) may be connected to each other. For example, the first body 511 and the second body 513 may be coupled by at least one of diffusion bonding, brazing, and laser welding.

According to an embodiment, the support 530 may support the first body 511 and the second body 513 such that the shape of an inner space formed between the first body 511 and the second body 513 is maintained. In an embodiment, the support 530 may be configured to have a pillar shape. In an embodiment, the support 530 may have one side (e.g., one side in the z-axis direction) connected to the second body 513 and the other side (e.g., the other side in the -z-axis direction) connected to the wick 550 adjacent to the first body 511 in the inner space of the case 510 formed by the coupling of the first body 511 and the second body 513.

According to an embodiment, the wick 550 may include at least one of a first wire 551a, a second wire 551b, an opening 553, and a passage 555 to circulate a working fluid using the high-temperature heat transferred from the case 510. In an embodiment, the first wire 551a and the second wire 551b may cause the size (e.g., the fourth thickness T4) of the heat-dissipating structure 500a to be determined according to a second thickness T2 (e.g., the length in the z-axis direction). In an embodiment, the wick 550 may be made of a stainless steel material. For example, the wick 550 may be made of a stainless steel material of 304 low (L) (or 316L) carbon steel material, copper, and/or a Cu alloy.

According to an embodiment, the first wire 551a may cause at least one opening 553 to be configured according to the arrangement with the second wire 551b. In an embodiment, the first wire 551a may be configured to have a wave shape. In this case, the first wire 551a may form, due to the wave shape, an empty space (e.g., a peak and a valley of a wave) in which the second wire 551b may be disposed. In an embodiment, the first wire 551a may be disposed to face a first direction (e.g., the y-axis direction). In an embodiment, multiple first wires 551a may be configured, and may be arranged side by side by a specified interval in a second direction (e.g., the x-axis direction). In addition, one first wire 551a among the multiple first wires 551a may have a wave shape of a waveform opposite to that of another adjacent first wire 551a. In an embodiment, the multiple first wires 551a may be disposed adjacent to the first body 511 in the inner space of the case 510. For example, the multiple first wires 551a may be disposed adjacent to the second surface of the first body 511 in a state of being substantially parallel to the second surface (e.g., the surface in the z-axis direction) of the first body 511. The first wire 551a may cause the size (e.g., a third thickness T3) of the channel 570 to be determined according to the arrangement in the inner space of the case 510.

According to an embodiment, the second wire 551b may cause the at least one opening 553 to be configured according to the arrangement with the first wire 551a. In an embodiment, the second wire 551b may be configured to have a wave shape. For example, the second wire 551b may be disposed to face the second direction (e.g., the x-axis direction) in the empty space (e.g., a peak and a valley of a wave) formed due to the shape (e.g., a wave shape) of the first wire 551a. In an embodiment, multiple second wires 551b may be configured, and may be arranged side by side by a specified interval in the first direction (e.g., the y-axis direction). In addition, one second wire 551b among the multiple second wires 551b may have a wave shape of a waveform opposite to that of another adjacent second wire 551b. In an embodiment, the multiple second wires 551b may be disposed adjacent to the first body 511 in the inner space of the case 510. For example, the multiple second wires 551b may be disposed adjacent to the second surface of the first body 511 in a state of being substantially parallel to the second surface (e.g., the surface in the z-axis direction) of the first body 511. The second wire 551b may cause the size (e.g., the third thickness T3) of the channel 570 to be determined according to the arrangement in the inner space of the case 510.

According to an embodiment, each of the first wire 551a and the second wire 551b may have the second thickness T2 (e.g., the length in the z-axis direction). For example, the first wire 551a and the second wire 551b cross to correspond by a wave shape, in different directions (e.g., the x-axis direction and the y-axis direction), so that each of the first wire 551a and the second wire 551b may have the second thickness T2 of about 15 to about 20 µm. The second thickness T2 may correspond to the size of the wick 550.

According to an embodiment, the opening 553 may cause a working fluid (e.g., a working fluid converted from a liquid state into a gaseous state) to move from the wick 550 to the channel 570. In an embodiment, the opening 553 may be configured as the multiple first wires 551a and the multiple second wires 551b cross each other at a specified interval. In an embodiment, multiple openings 553 may be configured such that the number of the multiple openings corresponds to the number of the multiple first wires 551a and the multiple second wires 551b which cross each other. In an embodiment, the opening 553 may be disposed to face a third direction (e.g., the z-axis direction).

According to an embodiment, the size of the opening 553 may be determined based on an internal pressure of the wick 550 and a flow resistance of a working fluid. For example, the opening 553 may have a diameter of about 50 to about 90 µm determined as the size of the opening such that the difference between the internal pressure of the wick 550 and the flow resistance of the working fluid satisfies at least a positive integer. In this case, a substantial length (e.g., the length in the y-axis direction) of the heat-dissipating structure 500a may be about 104 mm.

According to an embodiment, the passage 555 may store a working fluid in the liquid state. For example, the passage 555 may cause the working fluid in the liquid state to circulate along the passage 555. In an embodiment, the passage 555 may receive high-temperature heat from the first body 511. In this case, the passage 555 may convert the working fluid in the liquid state into the working fluid in the gaseous state by the received high-temperature heat. In addition, the passage 555 may move the working fluid in the gaseous state converted by the high-temperature heat to the channel 570 through the opening 553.

According to an embodiment, the channel 570 may convert the working fluid in the gaseous state introduced from the wick 550 through the opening 553 into the working fluid in the liquid state. For example, the working fluid in the gaseous state may be introduced into the channel 570 through the opening 553. In addition, the channel 570 may cause the working fluid in the gaseous state introduced through the opening 553 to circulate in the inner space. In an embodiment, the working fluid in the gaseous state circulates and is thus converted into the working fluid in the liquid state, so that the channel 570 may again move the working fluid in the liquid state to the passage 555 through the opening 553. In an embodiment, the channel 570 may have the third thickness T3 (e.g., the length in the z-axis direction). For example, the third thickness T3 of the channel 570 may be determined by the remaining inner space other than the inner space in which the wick 550 is disposed among the inner space of the case 510. In an embodiment, the channel 570 may have the third thickness T3 of about 100 to about 110 µm.

According to an embodiment, the heat-dissipating structure 500a may include a working fluid circulating in the inside thereof. In an embodiment, the working fluid may circulate in the wick 550 and the channel 570 through the opening 553 as the state of the working fluid is changed from the liquid state (or gaseous state) to the gaseous state (or liquid state). In an embodiment, the working fluid may be configured by one of water, a water-acetone mixed solution, and a water-ethanol mixed solution.

According to various embodiments, a filling ratio of a working fluid filled in the heat-dissipating structure 500a may be determined based on [Equation 1].

$$η = \frac{{V}_{f w}}{{V}_{p}} \times 100 \% = \frac{{V}_{f w}}{{V}_{s w}} \times 100 \%$$

In various embodiments,

$$\begin{matrix}{V}_{f w} = t h e v o l u m e o f t h e w a t e r f i l l e d i n t h e U T H P ( u l t r a \\ - t h i n f l a t t e n e d h e a t p i p e s ) \\ {V}_{p} = t h e t o t a l v o l u m e o f t h e p o r e s i n s i d e t h e w i c k \\ {V}_{s w} = t h e v o l u m e o f s a t u r a t e d w a t e r i n t h e w i c k\end{matrix}$$

In various embodiments, the filling ratio of the working fluid filled in the heat-dissipating structure 500a may be determined to be 90% to 110%, based on [Equation 1] described above.

FIG. 5B is a cross-sectional view illustrating a part of a heat-dissipating structure according to various embodiments. In various embodiments, FIG. 5B may be a cross-sectional view taken along line A-A′ of FIG. 4 and viewed in the y-axis direction of FIG. 4. In various embodiments, FIG. 5B may have a structure in which the wick 550 of FIG. 5A is disposed in substantially parallel to the z-axis direction. In various embodiments, FIG. 5B may be a view illustrating a structure of a water-cooled heat-dissipating member (e.g., a heat-pipe, a vapor chamber).

According to various embodiments, an electronic device (e.g., the electronic device 400 of FIG. 4) may include a heat-dissipating structure 500b (e.g., the heat-dissipating structure 410 of FIG. 4) identical to or similar to the shape of FIG. 5B in order to reduce the size (e.g., the length in the z-axis direction in FIG. 3) thereof in a state of maintaining a heat-dissipating effect (e.g., emission to the outside) of heat generated from an electronic component (e.g., the electronic component 401 of FIG. 4). In various embodiments, the heat-dissipating structure 500b may include at least one of a case 510, a support 530, a wick 550, and a channel 570. In various embodiments, the channel 570 may refer to a part of an inner space formed by the case 510, and may be dependently included in a component of the electronic device 400 according to whether the case 510 is included in the electronic device 400.

According to various embodiments, the case 510 may include at least one of a first body 511 and a second body 513 in order to absorb heat generated from the electronic component 401, transfer the heat to the inner space, and then radiate the heat to the inside (e.g., the inside of the housing 110 of FIG. 1) of the electronic device 400. In various embodiments, the first body 511 and the second body 513 may cause the size (e.g., a fourth thickness T4) of the heat-dissipating structure 500b to be determined according to a first thickness T1 (e.g., the length in the z-axis direction). According to various embodiments, the first thicknesses T1 of the first body 511 and/or the second body 513 are shown as being substantially the same, but may be different from each other. For example, the thickness of the first body 511 may be the first thickness T1, and the thickness of the second body 513 may be configured to have a thickness different from the first thickness T1. In various embodiments, the fourth thickness T4 related to the size of the heat-dissipating structure 500b may have a thickness of about 0.23 mm.

According to various embodiments, the first body 511 may absorb high-temperature heat from the electronic component 401 through a part of a first surface (e.g., the surface in the -z-axis direction) thereof. In various embodiments, the first body 511 may radiate the absorbed high-temperature heat through another part of the first surface. In various embodiments, the first body 511 may be configured to have a shape corresponding to the shape of the electronic component 401 in consideration of the first surface being in contact with the electronic component 401. In various embodiments, the first body 511 may be configured to have a shape which can receive the wick 550, in consideration of the wick 550 being disposed on a second surface (e.g., the surface in the z-axis direction) thereof.

According to various embodiments, the second body 513 may form an inner space of the case 510 such that at least one of the support 530, the wick 550, and the channel 570 is positioned inside the case 510. In various embodiments, both sides (e.g., one side in the y-axis direction and the other side in the -y-axis direction) of the second body 513 may protrude toward the second surface (e.g., the surface in the z-axis direction) of the first body 511. In various embodiments, the protruding both sides of the second body 513 may be at least partially coupled to the second surface of the first body 511. According to various embodiments, the first body 511 and the second body 513 may be coupled by various structures such as the first body 511 protruding toward the first surface or the first body 511 and the second body 513 protruding toward different surfaces (e.g., the first surface and the second surface). In various embodiments, when the high-temperature heat absorbed through the first body 511 is transferred to the inner space, the second body 513 may radiate the high-temperature heat toward an opposite direction (e.g., the z-axis direction) to a direction (e.g., the -z-axis direction) in which the first body 511 is positioned.

According to various embodiments, each of the first body 511 and the second body 513 may have the first thickness T1 (e.g., the length in the z-axis direction). For example, each of the first body 511 and the second body 513 may have the first thickness T1 of about 30 µm after being etched. For another example, the first body 511 (or the second body 513) may have the first thickness T1 of about 30 µm as a sheet-shaped flat plate which is not etched.

According to various embodiments, the support 530 may support the first body 511 and the second body 513 such that the shape of an inner space formed between the first body 511 and the second body 513 is maintained. In various embodiments, the support 530 may be configured to have a pillar shape. In various embodiments, the support 530 may have one side (e.g., one side in the z-axis direction) connected to the second body 513 and the other side (e.g., the other side in the -z-axis direction) connected to the first body 511 in the inner space of the case 510 formed by the coupling of the first body 511 and the second body 513. In various embodiments, the support 530 may be disposed on each of both sides of the wick 550 between the first body 511 and the second body 513. For example, multiple supports 530 may be disposed at a specified interval (e.g., the same interval) along a specified direction (e.g., the x-axis direction) on the both sides of the wick 550. In various embodiments, the supports 530 are disposed on the both sides of the wick 550, so that the fourth thickness T4 of the heat-dissipating structure 500b may be configured to be thinner than the fourth thickness T4 of the heat-dissipating structure 500a illustrated in FIG. 5A.

According to various embodiments, the wick 550 may include at least one of a first wire 551a, a second wire 551b, an opening 553, and a passage 555 to circulate a working fluid using the high-temperature heat transferred from the case 510. In various embodiments, the first wire 551a and the second wire 551b may cause the size (e.g., the fourth thickness T4) of the heat-dissipating structure 500b to be determined according to a fifth thickness T5 (e.g., the length in the z-axis direction). In various embodiments, the wick 550 may be disposed in substantially parallel to the z-axis direction in the inner space formed between the first body 511 and the second body 513, unlike the wick of FIG. 5A.

According to various embodiments, the first wire 551a may cause at least one opening 553 to be configured according to the arrangement with the second wire 551b. In various embodiments, the first wire 551a may be configured to have a wave shape. In this case, the first wire 551a may form, due to the wave shape, an empty space (e.g., a peak and a valley of a wave) in which the second wire 551b may be disposed. In various embodiments, the first wire 551a may be disposed to face a third direction (e.g., the z-axis direction). In various embodiments, multiple first wires 551a may be configured, and may be arranged side by side by a specified interval in a first direction (e.g., the y-axis direction). In addition, one first wire 551a among the multiple first wires 551a may have a wave shape of a waveform opposite to that of another adjacent first wire 551a.

According to various embodiments, the second wire 551b may cause the at least one opening 553 to be configured according to the arrangement with the first wire 551a. In various embodiments, the second wire 551b may be configured to have a wave shape. For example, the second wire 551b may be disposed to face the first direction (e.g., the y-axis direction) in the empty space (e.g., a peak and a valley of a wave) formed due to the shape (e.g., a wave shape) of the first wire 551a. In various embodiments, multiple second wires 551b may be configured, and may be arranged side by side by a specified interval in the third direction (e.g., the z-axis direction). In addition, one second wire 551b among the multiple second wires 551b may have a wave shape of a waveform opposite to that of another adjacent second wire 551b.

According to various embodiments, each of the first wire 551a and the second wire 551b may have a second thickness T2 (e.g., the second thickness T2 of FIG. 5A). For example, the first wire 551a and the second wire 551b cross to correspond by a wave shape, in different directions (e.g., the y-axis direction and the z-axis direction), so that each of the first wire 551a and the second wire 551b may have the second thickness T2 of about 15 to about 20 µm.

According to various embodiments, the opening 553 may cause a working fluid (e.g., a working fluid converted from a liquid state into a gaseous state) to move from the wick 550 to the channel 570. In various embodiments, the opening 553 may be configured as the multiple first wires 551a and the multiple second wires 551b cross each other at a specified interval. In various embodiments, multiple openings 553 may be configured such that the number of the multiple openings corresponds to the number of the multiple first wires 551a and the multiple second wires 551b which cross each other. In various embodiments, the opening 553 may be disposed to face a second direction (e.g., the x-axis direction).

According to various embodiments, the size of the opening 553 may be determined based on an internal pressure of the wick 550 and a flow resistance of a working fluid. For example, the opening 553 may have a diameter of about 50 to about 90 µm determined as the size of the opening such that the difference between the internal pressure of the wick 550 and the flow resistance of the working fluid satisfies at least a positive integer.

According to various embodiments, the passage 555 may store a working fluid in the liquid state. For example, the passage 555 may cause the working fluid in the liquid state to circulate along the passage 555. In various embodiments, the passage 555 may be disposed at a position adjacent to the -x-axis direction. In various embodiments, the passage 555 may receive high-temperature heat from the first body 511. In this case, the passage 555 may convert the working fluid in the liquid state into the working fluid in the gaseous state by the received high-temperature heat. In addition, the passage 555 may move the working fluid in the gaseous state converted by the high-temperature heat to the channel 570 through the opening 553.

According to various embodiments, the channel 570 may convert the working fluid in the gaseous state introduced from the wick 550 through the opening 553 into the working fluid in the liquid state. For example, the working fluid in the gaseous state may be introduced into the channel 570 through the opening 553. In addition, the channel 570 may cause the working fluid in the gaseous state introduced through the opening 553 to circulate in the inner space. In various embodiments, the channel 570 may be disposed in an opposite direction (e.g., the x-axis direction) to the passage 555 with the wick 550 interposed therebetween. In various embodiments, the working fluid in the gaseous state circulates and is thus converted into the working fluid in the liquid state, so that the channel 570 may again move the working fluid in the liquid state to the passage 555 through the opening 553.

According to various embodiments, the heat-dissipating structure 500b may include a working fluid circulating in the inside thereof. In an embodiment, the working fluid may circulate in the wick 550 and the channel 570 through the opening 553 as the state of the working fluid is changed from the liquid state (or gaseous state) to the gaseous state (or liquid state).

FIG. 5C is a cross-sectional view illustrating a part of an electronic device according to various embodiments. In various embodiments, FIG. 5C may be a cross-sectional view taken along line A-A′ of FIG. 4 and viewed in the z-axis direction of FIG. 4.

According to various embodiments, an electronic device 590 (e.g., the electronic device 400 of FIG. 4) may include at least one of a support member 560, an adhesive member 565, a heat-dissipating structure 500, a first liquid heat-dissipating member 570, a second liquid heat-dissipating member 575, and a printed circuit board 580.

According to various embodiments, the support member 560 (e.g., the first support member 311 of FIG. 3) may be connected to the heat-dissipating structure 500 through the adhesive member 565. In various embodiments, the support member 560 may cause at least one of the heat-dissipating structure 500, the first liquid heat-dissipating member 570, and the second liquid heat-dissipating member 575 to be disposed between the printed circuit board 580 and the support member 560.

According to various embodiments, the heat-dissipating structure 500 may include at least one of the heat-dissipating structure 500a of FIG. 5A and the heat-dissipating structure 500b of FIG. 5B. In various embodiments, the heat-dissipating structure 500 may be configured to have a size of a fourth thickness T4 (e.g., the fourth thickness T4 of FIGS. 5A or 5B). In various embodiments, the heat-dissipating structure 500 may be disposed between the support member 560 and the first liquid heat-dissipating member 570.

According to various embodiments, the first liquid heat-dissipating member 570 may be disposed between the heat-dissipating structure 500 and the printed circuit board 580. In various embodiments, the first liquid heat-dissipating member 570 may absorb heat generated from an electronic component (e.g., a processor 581) on the printed circuit board 580 and transfer the heat to the heat-dissipating structure 500.

According to various embodiments, the second liquid heat-dissipating member 575 may be applied in the z-axis direction of the first liquid heat-dissipating member 570. In various embodiments, the second liquid heat-dissipating member 575 may absorb heat generated from the electronic component (e.g., the processor 581) on the printed circuit board 580 and transfer the heat to the first liquid heat-dissipating member 570. In various embodiments, the second liquid heat-dissipating member 575 may be configured to have a sixth thickness T6 (e.g., 0.05 mm) which is thinner than an interval (e.g., 0.07 mm) formed between the first liquid heat-dissipating member 570 and the electronic component (e.g., the processor 581) on the printed circuit board 580.

According to various embodiments, the processor 581 (e.g., the electronic component 401 of FIG. 4) may be disposed on the printed circuit board 580 in the -z-axis direction. In various embodiments, the processor 581 may be disposed adjacent to the second liquid heat-dissipating member 575 in the -z-axis direction. In various embodiments, the processor 581 may generate heat according to an operation for executing a function (e.g., video playback) of the electronic device 590. In this case, the generated heat may be transferred to the second liquid heat-dissipating member 575.

According to various embodiments, the electronic device 590 may reduce a seventh thickness T7 including the support member 560, the adhesive member 565, the heat-dissipating structure 500, the first liquid heat-dissipating member 570, the second liquid heat-dissipating member 575, and the processor 581 to a specified length (e.g., 1.87 mm) in the z-axis direction, based on the fourth thickness T4 of the heat-dissipating structure 500 and the sixth thickness T6 of the second liquid heat-dissipating member 575. In various embodiments, when the electronic device 590 may be configured as a foldable electronic device in which multiple displays (e.g., a first display and a second display) are connected through a connection member (e.g., a hinge structure), the seventh thickness T7 may be configured to correspond to the thickness of the corresponding electronic device.

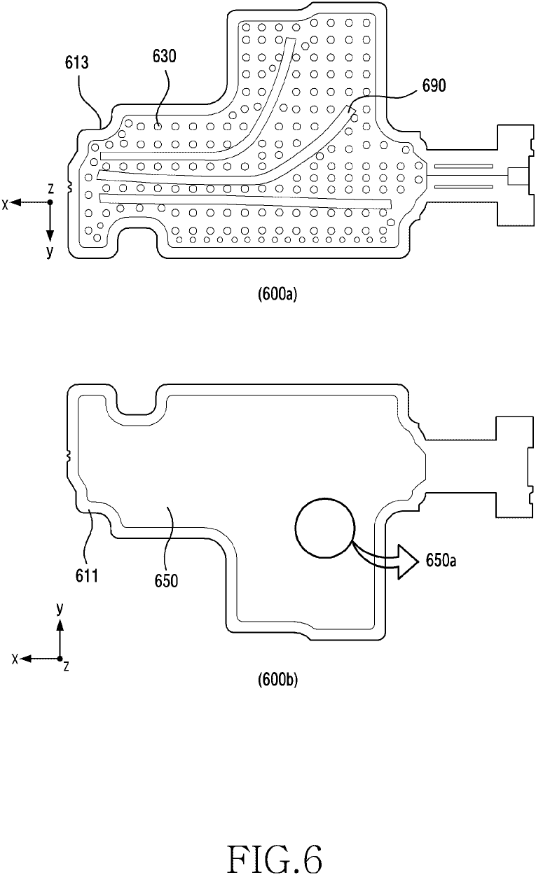

FIG. 6 is a diagram illustrating an example heat-dissipating structure according to various embodiments. In an embodiment, FIG. 6 may be a view illustrating an internal structure of a heat-dissipating structure (e.g., the heat-dissipating structure 500a of FIG. 5A) is exposed on a plane according to separation of a case (e.g., the case 510 of FIG. 5A).

Referring to a first state 600a, when viewed from the z-axis direction of FIG. 5A, the heat-dissipating structure 500a may include a second body 613 (e.g., the second body 513 of FIG. 5A) and multiple supports 630 (e.g., the support 530 of FIG. 5A). In an embodiment, the second body 613 may be disposed in a direction substantially parallel to a plane formed between the x-axis direction and the y-axis direction. In an embodiment, the multiple supports 630 may be disposed in a direction substantially perpendicular to the plane formed between the x-axis direction and the y-axis direction. For example, the multiple supports 630 are disposed substantially perpendicular to the second body 613, so that an inner space of the case 510 is formed when the second body 613 is coupled to a first body 611 (e.g., the first body 511 of FIG. 5A). In various embodiments, the heat-dissipating structure 500a may further include a wire wick 690. The wire wick 690 together with a wick 650 (e.g., the wick 550 of FIG. 5A) may cause a greater amount of working fluid to circulate. For example, the wire wick 690 may be disposed in a direction substantially parallel to the plane formed between the x-axis direction and the y-axis direction.

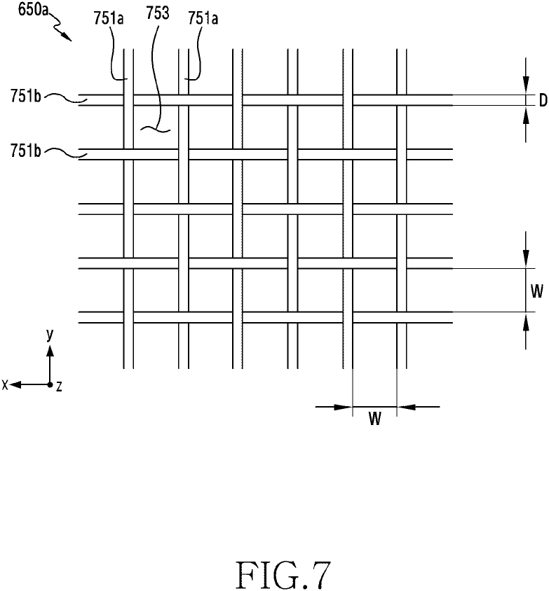

Referring to a second state 600b, when viewed from the -z-axis direction of FIG. 5A, the heat-dissipating structure 500a may include the first body 611 and the wick 650. In an embodiment, the first body 611 may be disposed in a direction substantially parallel to a plane formed between the x-axis direction and the y-axis direction. In an embodiment, the wick 650 may be disposed in a direction substantially parallel to the plane formed between the x-axis direction and the y-axis direction. For example, the wick 650 may be configured to correspond to a shape in which the supports 630 in the first state 600a are distributed. In an embodiment, the wick 650 may be expanded to a screen mesh structure 650a. The screen mesh structure 650a may be described in greater detail below with reference to FIG. 7.

FIG. 7 is an enlarged plan view of a wick of a heat-dissipating structure according to various embodiments. In an embodiment, the screen mesh structure 650a may be an enlarged view of a part of the wick 650 of FIG. 6.

According to an embodiment, the screen mesh structure 650a may have a structure in which multiple first wires 751a (e.g., the first wire 551a of FIG. 5A) and multiple second wires 751b (e.g., the second wire 551b of FIG. 5A) cross each other. For example, in the screen mesh structure 650a, the multiple first wires 751a facing a first direction (e.g., the y-axis direction) may be arranged side by side in a second direction (e.g., the x-axis direction), and the multiple second wires 751b facing the second direction (e.g., the x-axis direction) may be arranged side by side in the first direction (e.g., the y-axis direction). In addition, in the screen mesh structure 650a, a structure, in which a first wire 751a is disposed at the upper side (e.g., the z-axis direction) and a second wire 751b is disposed at the upper side (e.g., the z-axis direction) at adjacent cross points among multiple cross points where the multiple first wires 751a and the multiple second wires 751b cross each other, may repeat. In an embodiment, each of the first wires 751a (or the second wires 751b) may have a specified diameter D. For example, the specified diameter D may be a diameter for minimizing the size (e.g., the fourth thickness T4 of FIG. 5A) of a heat-dissipating structure (e.g., the heat-dissipating structure 500a of FIG. 5A).

According to an embodiment, the screen mesh structure 650a may have multiple openings 753 (e.g., the opening 553 of FIG. 5A) formed by the multiple first wires 751a and the multiple second wires 751b. In an embodiment, the multiple openings 753 may refer to empty spaces formed by crossing the multiple first wires 751a and the multiple second wires 751b. In an embodiment, each of the multiple openings 753 may have a specified width W. For example, each of the multiple openings 753 may have a width W for allowing a capillary pressure corresponding to an internal pressure of a wick (e.g., the wick 550 of FIG. 5A) and/or a flow resistance corresponding to a pressure drop of a working fluid circulating in the wick 550 to satisfy a specified value (e.g., a positive integer).

According to various embodiments, the capillary pressure corresponding to the internal pressure of the wick 550 may be determined based on [Equation 2].

$$\left(Δ {P}_{e}\right) m a x = \frac{2 σ}{γ e f f}$$

In various embodiments, when the wick 550 has a wire structure (e.g., the wire wick 690 of FIG. 6), σ = surface tension and γ_{eƒƒ} = capillary radius of wick. In various embodiments, when the wick 550 has the screen mesh structure 650a, γ_{eƒƒ} = (wire dimeter + opening)/2 .

According to various embodiments, the flow resistance corresponding to the pressure drop of the working fluid circulating in the wick 550 may be determined based on [Equation 3].

$$Δ {p}_{l} = \int {}_{0}^{L} \frac{d {p}_{i}}{d x} d x = \frac{{μ}_{l} Q {L}_{e f f}}{K {A}_{w} {ρ}_{l} {h}_{f g}}$$

In various embodiments, when the wick 550 has a wire structure,

$$\begin{matrix}K = p e r m e a b i l i t y o f w i c k , \\ Q = i n p u t p o w e r , {p}_{l} = d e n s i t y o f l i q u i d , {μ}_{l} = v i s c o s i t y o f l i q u i d , \\ {A}_{w} = c r o s s s e c t i o n a l a r e a o f w i c k , {h}_{f g} = l a t e n t h e a t o f \\ v a p o r i z a t i o n , a n d {L}_{e f f} = e f f e c t i v e l e n g t h o f v a p o r c h a m b e r .\end{matrix}$$

In various embodiments, when the wick 550 has the screen mesh structure 650a,

$$\begin{matrix}K = \frac{{d}^{2} {∈}^{3}}{122 ( 1 - {∈}^{2}} , d = w i r e d i a m e t e r , ∈ = 1 - \frac{1.05 π N d}{4} , a n d \\ N = m e s h n u m b e r .\end{matrix}$$

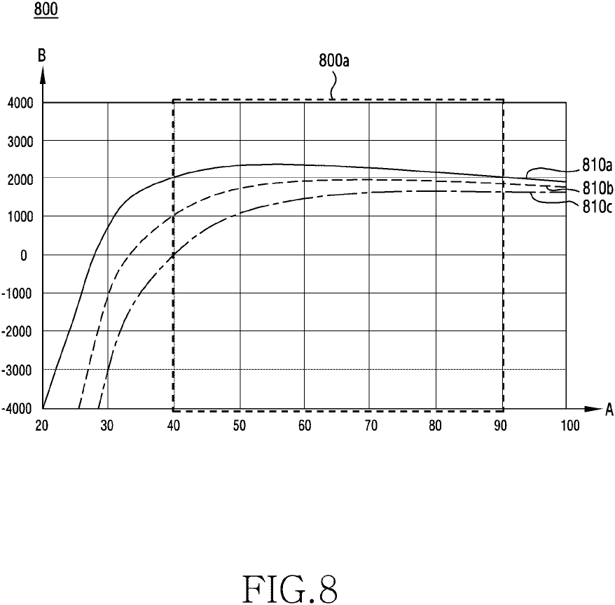

FIG. 8 is a graph illustrating a relationship between an internal pressure of a wick and a flow resistance of a working fluid according to the size of an opening of a heat-dissipating structure according to various embodiments. In an embodiment, FIG. 8 may be a graph 800 in which the size of an opening is indicated on the A axis and a difference between an internal pressure of a wick and a flow resistance of a working fluid is indicated on the B axis.

According to an embodiment, in a heat-dissipating structure (e.g., the heat-dissipating structure 500a of FIG. 5A), the size of an opening (e.g., the opening 553 of FIG. 5A) for connecting between a wick (e.g., the wick 550 of FIG. 5A) and a channel (e.g., the channel 570 of FIG. 5A) may be determined based on an internal pressure (e.g., a capillary pressure) of the wick 550 and a flow resistance (e.g., a pressure drop) of a working fluid. In this case, the working fluid may be a working fluid in a liquid state, which circulates inside the wick 550. In an embodiment, in relation to the opening 553, when the difference between the internal pressure of the wick 550 and the flow resistance of the working fluid has an at least specified value, a length (e.g., the width W of FIG. 7) for allowing the at least specified value to be configured may correspond to the size of the opening 553. For example, when the size (unit: µm) of the opening 553 indicated on the B axis in the graph 800 is greater than or equal to a specified value (e.g., about 40 µm), the difference between the internal pressure of the wick 550 indicated on the A-axis and the flow resistance of the working fluid may be configured to be a specified value (e.g., greater than 0).

According to an embodiment, the opening 553 may cause the internal pressure of the wick 550 and the flow resistance of the working fluid to be changed based on a substantial length of the heat-dissipating structure 500a. For example, the opening 553 may cause the internal pressure of the wick 550 and the flow resistance of the working fluid to be changed even when the opening 553 has substantially the same size according to a substantial length (e.g., a length including a curved part of the heat-dissipating structure) of the heat-dissipating structure 500a corresponding to each of a first curve 810a, a second curve 810b, and a third curve 810c. Referring to the first curve 810a, when the substantial length of the heat-dissipating structure 500a is a first length (e.g., about 64 mm), the opening 553 may cause the internal pressure of the wick 550 and the flow resistance of the working fluid to be configured as a positive integer at a size of about 28 µm or greater. Referring to the second curve 810b, when the substantial length of the heat-dissipating structure 500a is a second length (e.g., about 84 mm), the opening 553 may cause the internal pressure of the wick 550 and the flow resistance of the working fluid to be configured as a positive integer at a size of about 35 µm or greater. Referring to the third curve 810c, when the substantial length of the heat-dissipating structure 500a is a third length (e.g., about 104 mm), the opening 553 may cause the internal pressure of the wick 550 and the flow resistance of the working fluid to be configured as a positive integer at a size of about 41 µm or greater.

According to an embodiment, when the size of the opening 553 is included in an optimization section 800a, the heat-dissipating structure 500a, which may be configured to have multiple lengths corresponding to the first curve 810a, the second curve 810b, and the third curve 810c, may cause the internal pressure of the wick 550 and the flow resistance of the working fluid to be configured as a positive integer. For example, the optimization section 800a may be a size section of the opening 553 for allowing the internal pressure of the wick 550 and the flow resistance of the working fluid to be configured as a positive integer even when the heat-dissipating structure 500a has different lengths.

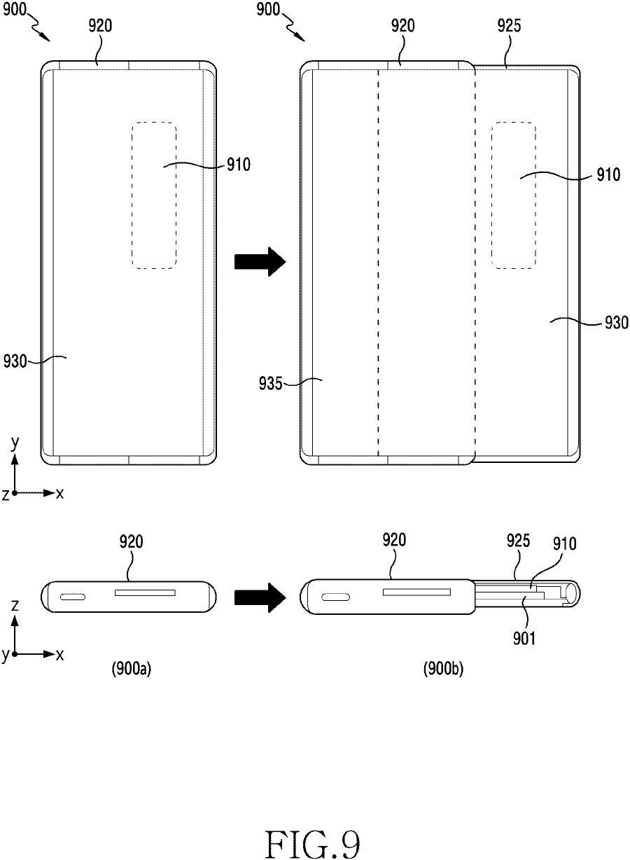

FIG. 9 is a diagram illustrating an example heat-dissipating structure disposed in an electronic device according to various embodiments.

Referring to FIG. 9, an electronic device 900 (e.g., the electronic device 100 of FIG. 1) according to various embodiments may further include a second housing 925 capable of sliding from a first housing 920 (e.g., the housing 110 of FIG. 1). In various embodiments, the electronic device 900 may move a position of a heat-dissipating structure 910 (e.g., the heat-dissipating structure 410 of FIG. 4) according to a change from a first state 900a to a second state 900b corresponding to the sliding operation of the second housing 925.

Referring to the first state 900a, the heat-dissipating structure 910 may be positioned to overlap the first housing 920 in the z-axis direction. In this case, the heat-dissipating structure 910 may be positioned to overlap the first housing 920 in a state of being disposed in the second housing 925. In various embodiments, when the second housing 925 does not slide in the x-axis direction from the first housing 920, the electronic device 900 may display a screen through a first display 930 (e.g., the display 101 of FIG. 1).

Referring to the second state 900b, the heat-dissipating structure 910 may be positioned to overlap the second housing 925 in the z-axis direction. In this case, the heat-dissipating structure 910 may not overlap the first housing 920 according to the sliding operation of the second housing 925 in the x-axis direction. In various embodiments, at least a part of the heat-dissipating structure 910 may be disposed adjacent to the surface of an electronic component 901 (e.g., the electronic component 401 of FIG. 4) disposed in the second housing 925. In various embodiments, when the second housing 925 slides in the x-axis direction from the first housing 920, the electronic device 900 may display a screen through at least one of the first display 930 and a second display 935.

According to various embodiments, the electronic device 900 may move the second housing 925 from the inside of the first housing 920 toward the x-axis direction by an extension member such as a roller disposed in the -x-axis direction of the first housing 920. In this case, the second display 935 overlapping the first display 930 in the z-axis direction may be exposed to the outside as in the second state 900b. In various embodiments, the electronic device 900 may move the second housing 920, which has been moved in the x-axis direction from the inside of the first housing 920, to the inside (e.g., the -x-axis direction) of the first housing 920 by the extension member such as the roller disposed in the -x-axis direction of the first housing 920. In this case, the second display 935 exposed to the outside may at least partially overlap the first display 930 in the z-axis direction.

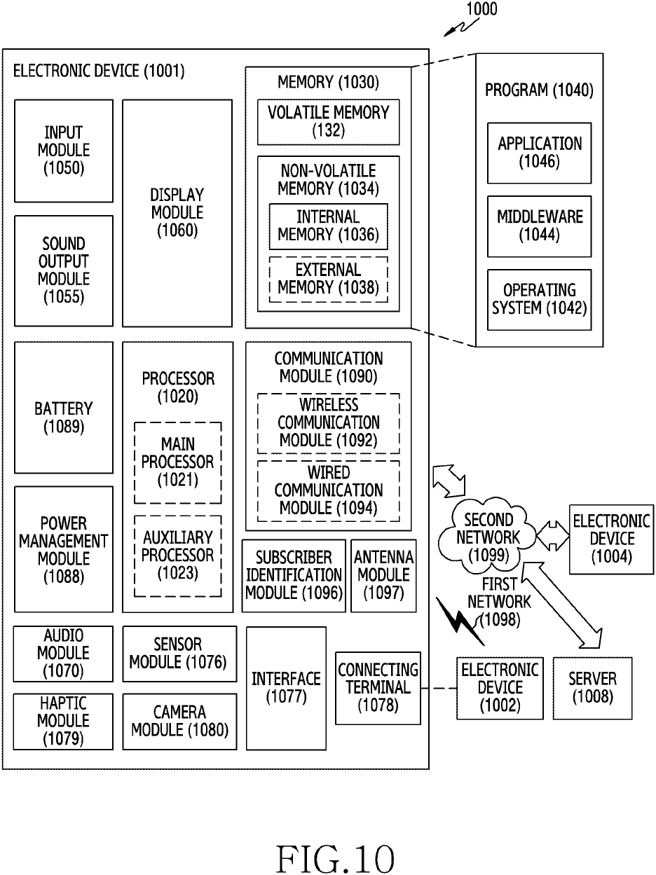

FIG. 10 is a diagram illustrating an example electronic device in a network environment 100 according to various embodiments.

Referring to FIG. 10, the electronic device 1001 in the network environment 1000 may communicate with an electronic device 1002 via a first network 1098 (e.g., a short-range wireless communication network), or an electronic device 1004 or a server 1008 via a second network 1099 (e.g., a long-range wireless communication network). According to an embodiment, the electronic device 1001 may communicate with the electronic device 1004 via the server 1008. According to an embodiment, the electronic device 1001 may include a processor 1020, memory 1030, an input module 1050, a sound output module 1055, a display module 1060, an audio module 1070, a sensor module 1076, an interface 1077, a connecting terminal 1078, a haptic module 1079, a camera module 1080, a power management module 1088, a battery 1089, a communication module 1090, a subscriber identification module (SIM) 1096, or an antenna module 1097. In various embodiments, at least one of the components (e.g., the connecting terminal 1078) may be omitted from the electronic device 1001, or one or more other components may be added in the electronic device 1001. In various embodiments, some of the components (e.g., the sensor module 1076, the camera module 1080, or the antenna module 1097) may be implemented as a single component (e.g., the display module 1060).

The processor 1020 may execute, for example, software (e.g., a program 1040) to control at least one other component (e.g., a hardware or software component) of the electronic device 1001 coupled with the processor 1020, and may perform various data processing or computation. According to an embodiment, as at least part of the data processing or computation, the processor 1020 may store a command or data received from another component (e.g., the sensor module 1076 or the communication module 1090) in volatile memory 1032, process the command or the data stored in the volatile memory 1032, and store resulting data in non-volatile memory 1034. According to an embodiment, the processor 1020 may include a main processor 1021 (e.g., a central processing unit (CPU) or an application processor (AP)), or an auxiliary processor 1023 (e.g., a graphics processing unit (GPU), a neural processing unit (NPU), an image signal processor (ISP), a sensor hub processor, or a communication processor (CP)) that is operable independently from, or in conjunction with, the main processor 1021. For example, when the electronic device 1001 includes the main processor 1021 and the auxiliary processor 1023, the auxiliary processor 1023 may be adapted to consume less power than the main processor 1021, or to be specific to a specified function. The auxiliary processor 1023 may be implemented as separate from, or as part of the main processor 1021.

The auxiliary processor 1023 may control, for example, at least some of functions or states related to at least one component (e.g., the display module 1060, the sensor module 1076, or the communication module 1090) among the components of the electronic device 1001, instead of the main processor 1021 while the main processor 1021 is in an inactive (e.g., sleep) state, or together with the main processor 1021 while the main processor 1021 is in an active (e.g., executing an application) state. According to an embodiment, the auxiliary processor 1023 (e.g., an image signal processor or a communication processor) may be implemented as part of another component (e.g., the camera module 1080 or the communication module 1090) functionally related to the auxiliary processor 1023. According to an embodiment, the auxiliary processor 1023 (e.g., the neural processing unit) may include a hardware structure specified for artificial intelligence model processing. An artificial intelligence model may be generated by machine learning. Such learning may be performed, e.g., by the electronic device 1001 where the artificial intelligence model is performed or via a separate server (e.g., the server 1008). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 1030 may store various data used by at least one component (e.g., the processor 1020 or the sensor module 1076) of the electronic device 1001. The various data may include, for example, software (e.g., the program 1040) and input data or output data for a command related thereto. The memory 1030 may include the volatile memory 1032 or the non-volatile memory 1034.

The program 1040 may be stored in the memory 1030 as software, and may include, for example, an operating system (OS) 1042, middleware 1044, or an application 1046.

The input module 1050 may receive a command or data to be used by another component (e.g., the processor 1020) of the electronic device 1001, from the outside (e.g., a user) of the electronic device 1001. The input module 1050 may include, for example, a microphone, a mouse, a keyboard, a key (e.g., a button), or a digital pen (e.g., a stylus pen).

The sound output module 1055 may output sound signals to the outside of the electronic device 1001. The sound output module 1055 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 1060 may visually provide information to the outside (e.g., a user) of the electronic device 1001. The display module 1060 may include, for example, a display, a hologram device, or a projector and control circuitry to control a corresponding one of the display, hologram device, and projector. According to an embodiment, the display module 1060 may include a touch sensor adapted to detect a touch, or a pressure sensor adapted to measure the intensity of force incurred by the touch.

The audio module 1070 may convert a sound into an electrical signal and vice versa. According to an embodiment, the audio module 1070 may obtain the sound via the input module 1050, or output the sound via the sound output module 1055 or an external electronic device (e.g., an electronic device 1002 (e.g., a speaker or a headphone)) directly or wirelessly coupled with the electronic device 1001.

The sensor module 1076 may detect an operational state (e.g., power or temperature) of the electronic device 1001 or an environmental state (e.g., a state of a user) external to the electronic device 1001, and then generate an electrical signal or data value corresponding to the detected state. According to an embodiment, the sensor module 1076 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1077 may support one or more specified protocols to be used for the electronic device 1001 to be coupled with the external electronic device (e.g., the electronic device 1002) directly or wirelessly. According to an embodiment, the interface 1077 may include, for example, a high definition multimedia interface (HDMI), a universal serial bus (USB) interface, a secure digital (SD) card interface, or an audio interface.

The connecting terminal 1078 may include a connector via which the electronic device 1001 may be physically connected with the external electronic device (e.g., the electronic device 1002). According to an embodiment, the connecting terminal 1078 may include, for example, an HDMI connector, a USB connector, an SD card connector, or an audio connector (e.g., a headphone connector).

The haptic module 1079 may convert an electrical signal into a mechanical stimulus (e.g., a vibration or a movement) or electrical stimulus which may be recognized by a user via his tactile sensation or kinesthetic sensation. According to an embodiment, the haptic module 1079 may include, for example, a motor, a piezoelectric element, or an electric stimulator.

The camera module 1080 may capture a still image or moving images. According to an embodiment, the camera module 1080 may include one or more lenses, image sensors, image signal processors, or flashes.

The power management module 1088 may manage power supplied to the electronic device 1001. According to an embodiment, the power management module 1088 may be implemented as at least part of, for example, a power management integrated circuit (PMIC).

The battery 1089 may supply power to at least one component of the electronic device 1001. According to an embodiment, the battery 1089 may include, for example, a primary cell which is not rechargeable, a secondary cell which is rechargeable, or a fuel cell.

The communication module 1090 may support establishing a direct (e.g., wired) communication channel or a wireless communication channel between the electronic device 1001 and the external electronic device (e.g., the electronic device 1002, the electronic device 1004, or the server 1008) and performing communication via the established communication channel. The communication module 1090 may include one or more communication processors that are operable independently from the processor 1020 (e.g., the application processor (AP)) and supports a direct (e.g., wired) communication or a wireless communication. According to an embodiment, the communication module 1090 may include a wireless communication module 1092 (e.g., a cellular communication module, a short-range wireless communication module, or a global navigation satellite system (GNSS) communication module) or a wired communication module 1094 (e.g., a local area network (LAN) communication module or a power line communication (PLC) module). A corresponding one of these communication modules may communicate with the external electronic device 1004 via the first network 1098 (e.g., a short-range communication network, such as Bluetooth™, wireless-fidelity (Wi-Fi) direct, or infrared data association (IrDA)) or the second network 1099 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 1092 may identify or authenticate the electronic device 1001 in a communication network, such as the first network 1098 or the second network 1099, using subscriber information (e.g., international mobile subscriber identity (IMSI)) stored in the subscriber identification module 1096.

The wireless communication module 1092 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 1092 may support a high-frequency band (e.g., the mmWave band) to achieve, e.g., a high data transmission rate. The wireless communication module 1092 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 1092 may support various requirements specified in the electronic device 1001, an external electronic device (e.g., the electronic device 1004), or a network system (e.g., the second network 1099). According to an embodiment, the wireless communication module 1092 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 1097 may transmit or receive a signal or power to or from the outside (e.g., the external electronic device) of the electronic device 1001. According to an embodiment, the antenna module 1097 may include an antenna including a radiating element including a conductive material or a conductive pattern formed in or on a substrate (e.g., a printed circuit board (PCB)). According to an embodiment, the antenna module 1097 may include a plurality of antennas (e.g., array antennas). In such a case, at least one antenna appropriate for a communication scheme used in the communication network, such as the first network 1098 or the second network 1099, may be selected, for example, by the communication module 1090 from the plurality of antennas. The signal or the power may then be transmitted or received between the communication module 1090 and the external electronic device via the selected at least one antenna. According to an embodiment, another component (e.g., a radio frequency integrated circuit (RFIC)) other than the radiating element may be additionally formed as part of the antenna module 1097.

According to various embodiments, the antenna module 1097 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 1001 and the external electronic device 1004 via the server 1008 coupled with the second network 1099. Each of the external electronic devices 1002 or 1004 may be a device of a same type as, or a different type, from the electronic device 1001. According to an embodiment, all or some of operations to be executed at the electronic device 101 may be executed at one or more of the external electronic devices 1002, 1004, or 1008. For example, if the electronic device 1001 should perform a function or a service automatically, or in response to a request from a user or another device, the electronic device 1001, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 1001. The electronic device 1001 may provide the outcome, with or without further processing of the outcome, as at least part of a reply to the request. To that end, a cloud computing, distributed computing, mobile edge computing (MEC), or client-server computing technology may be used, for example. The electronic device 1001 may provide ultra low-latency services using, e.g., distributed computing or mobile edge computing. In an embodiment, the external electronic device 1004 may include an internet-of-things (IoT) device. The server 1008 may be an intelligent server using machine learning and/or a neural network. According to an embodiment, the external electronic device 1004 or the server 1008 may be included in the second network 1099. The electronic device 1001 may be applied to intelligent services (e.g., smart home, smart city, smart car, or healthcare) based on 5G communication technology or IoT-related technology.

According to various example embodiments, a heat-dissipating structure (e.g., the heat-dissipating structure 500a of FIG. 5A) may include: a case (e.g., the case 510 of FIG. 5A) including: a first body (e.g., the first body 511 of FIG. 5A) and a second body (e.g., the second body 513 of FIG. 5A) spaced apart from each other; a wick (e.g., the wick 550 of FIG. 5A) disposed in a space between the first body and the second body, the wick including multiple wires (e.g., the first wire 551a and the second wire 551b of FIG. 5A) disposed in a first direction and in a second direction intersecting the first direction, and having a passage (e.g., the passage 555 of FIG. 5A) for a working fluid, the passage being formed along at least one opening (e.g., the opening 553 of FIG. 5A) formed between the multiple wires (the first wire 551a and the second wire 551b); and a channel (e.g., the channel 570 of FIG. 5A) formed between the first body and the wick and configured to move the working fluid through the at least one opening according to a change in a state of the working fluid, wherein the at least one opening is configured such that a size thereof is determined based on an internal pressure of the wick and a flow resistance of the working fluid.

According to various example embodiments, the at least one opening may be configured such that the size thereof is determined based on a difference between the internal pressure of the wick and the flow resistance of the working fluid having an at least specified value.

According to various example embodiments, the at least specified value may be a positive integer.

According to various example embodiments, the heat-dissipating structure may be configured such that the internal pressure of the wick and the flow resistance of the working fluid are changed based on a substantial length of the heat-dissipating structure facing the first direction.

According to various example embodiments, the substantial length of the heat-dissipating structure may be configured to include a curved part of the heat-dissipating structure.

According to various example embodiments, the wick may be configured to have at least one structure among a first structure having a length specified in the first direction and the second direction and a second structure having a length specified to be shorter in the second direction than the first structure.

According to various example embodiments, the case may be configured to have a first thickness in a third direction forming a specified angle with a plane between the first direction and the second direction.

According to various example embodiments, the wick may be configured to have a second thickness in the third direction.

According to various example embodiments, the channel may have a third thickness in the third direction, and a length obtained by summing the first thickness, the second thickness, and the third thickness and may be within a specified value.

According to various example embodiments, the case may comprise a stainless steel material.

According to various example embodiments, an electronic device (e.g., the electronic device 400 of FIG. 4) may include: a housing (e.g., the housing 110 of FIG. 1); a printed circuit board (e.g., the printed circuit board 402 of FIG. 4) disposed inside the housing and including an electronic component (e.g., the electronic component 401 of FIG. 4); and a heat-dissipating structure disposed adjacent to the electronic component 401, wherein the heat-dissipating structure includes: a case which includes: a first body and a second body spaced apart from each other and in which the second body is in contact with the electronic component; a wick disposed in a space between the first body and the second body, the wick including multiple wires (e.g., a first wire 551a and a second wire 551b) disposed in a first direction and in a second direction intersecting the first direction, and having a passage for a working fluid, the passage being formed along at least one opening formed between the multiple wires (the first wire 551a and the second wire 551b); and a channel formed between the first body and the wick and configured to move the working fluid through the at least one opening according to a change in a state of the working fluid, and the at least one opening is configured such that a size thereof is determined based on an internal pressure of the wick and a flow resistance of the working fluid.

According to various example embodiments, the at least one opening may be configured such that the size thereof is determined based on a difference between the internal pressure of the wick and the flow resistance of the working fluid having an at least specified value.

According to various example embodiments, the at least specified value may be a positive integer.

According to various example embodiments, the heat-dissipating structure may be configured such that the internal pressure of the wick and the flow resistance of the working fluid are changed based on a substantial length of the heat-dissipating structure facing the first direction.

According to various example embodiments, the substantial length of the heat-dissipating structure may include a curved part of the heat-dissipating structure.

According to various example embodiments, the wick may be configured to have at least one structure among a first structure having a length specified in the first direction and the second direction and a second structure having a length specified to be shorter in the second direction than the first structure.

According to various example embodiments, the case may be configured to have a first thickness in a third direction forming a specified angle with a plane between the first direction and the second direction.

According to various example embodiments, the wick may be configured to have a second thickness in the third direction.

According to various example embodiments, the channel may have a third thickness in the third direction, and a length obtained by summing the first thickness, the second thickness, and the third thickness and may be within a specified value.

According to various example embodiments, the case may comprise a stainless steel material.

The electronic device according to various embodiments disclosed herein may be one of various types of electronic devices. The electronic devices may include, for example, a portable communication device (e.g., a smart phone), a computer device, a portable multimedia device, a portable medical device, a camera, a wearable device, a home appliance, or the like. The electronic device according to embodiments of the disclosure is not limited to those described above.

It should be appreciated that various embodiments of the disclosure and the terms used therein are not intended to limit the technological features set forth herein to particular embodiments and include various changes, equivalents, or alternatives for a corresponding embodiment. With regard to the description of the drawings, similar reference numerals may be used to designate similar or relevant elements. A singular form of a noun corresponding to an item may include one or more of the items, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C” may include all possible combinations of the items enumerated together in a corresponding one of the phrases. As used herein, such terms as “a first”, “a second”, “the first”, and “the second” may be used to simply distinguish a corresponding element from another, and does not limit the elements in other aspect (e.g., importance or order). It is to be understood that if an element (e.g., a first element) is referred to, with or without the term “operatively” or “communicatively”, as “coupled with/to” or “connected with/to” another element (e.g., a second element), the element may be coupled/connected with/to the other element directly (e.g., wiredly), wirelessly, or via a third element.

As used herein, the term “module” may include a unit implemented in hardware, software, or firmware, or any combination thereof, and may be interchangeably used with other terms, for example, “logic,” “logic block,” “component,” or “circuit”. The “module” may be a minimum unit of a single integrated component adapted to perform one or more functions, or a part thereof. For example, according to an embodiment, the “module” may be implemented in the form of an application-specific integrated circuit (ASIC).

According to various embodiments, each element (e.g., a module or a program) of the above-described elements may include a single entity or multiple entities. According to various embodiments, one or more of the above-described elements may be omitted, or one or more other elements may be added. Alternatively or additionally, a plurality of elements (e.g., modules or programs) may be integrated into a single element. In such a case, according to various embodiments, the integrated element may still perform one or more functions of each of the plurality of elements in the same or similar manner as they are performed by a corresponding one of the plurality of elements before the integration. According to various embodiments, operations performed by the module, the program, or another element may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. A heat-dissipating structure comprising:
a case comprising a first body and a second body spaced apart from each other;
a wick disposed in a space between the first body and the second body, the wick comprising multiple wires disposed in a first direction and in a second direction intersecting the first direction, and having a passage for a working fluid, the passage being formed along at least one opening formed between the multiple wires; and
a channel formed between the first body and the wick and configured to move the working fluid through the at least one opening according to a change in a state of the working fluid,
wherein the at least one opening has a size determined based on an internal pressure of the wick and a flow resistance of the working fluid.

2. The heat-dissipating structure of claim 1, wherein the size of the at least one opening is determined based on a difference between the internal pressure of the wick and the flow resistance of the working fluid having an at least specified value.

3. The heat-dissipating structure of claim 2, wherein the at least specified value is a positive integer.

4. The heat-dissipating structure of claim 1, wherein the heat-dissipating structure is configured such that the internal pressure of the wick and the flow resistance of the working fluid are changed based on a substantial length of the heat-dissipating structure facing the first direction.

5. The heat-dissipating structure of claim 4, wherein the substantial length of the heat-dissipating structure includes a curved part of the heat-dissipating structure.

6. The heat-dissipating structure of claim 1, wherein the wick has at least one structure among a first structure having a length specified in the first direction and the second direction and a second structure having a length specified to be shorter in the second direction than the first structure.

7. The heat-dissipating structure of claim 1, wherein the case is has a first thickness in a third direction forming a specified angle with a plane between the first direction and the second direction.

8. The heat-dissipating structure of claim 7, wherein the wick has a second thickness in the third direction.

9. The heat-dissipating structure of claim 8, wherein the channel has a third thickness in the third direction, and
a length obtained by summing the first thickness, the second thickness, and the third thickness is within a specified value.

10. The heat-dissipating structure of claim 1, wherein the case comprises a stainless steel material.

11. An electronic device comprising:
a housing;
a printed circuit board disposed inside the housing and comprising an electronic component; and
a heat-dissipating structure disposed adjacent to the electronic component,
wherein the heat-dissipating structure comprises:
a case comprising: a first body and a second body spaced apart from each other wherein the second body is in contact with the electronic component;
a wick disposed in a space between the first body and the second body, the wick comprising: multiple wires disposed in a first direction and in a second direction intersecting the first direction, and having a passage for a working fluid, the passage being formed along at least one opening formed between the multiple wires; and
a channel formed between the first body and the wick and configured to move the working fluid through the at least one opening according to a change in a state of the working fluid, and
the at least one opening having a size determined based on an internal pressure of the wick and a flow resistance of the working fluid.

12. The electronic device of claim 11, wherein the size of the at least one opening is determined based on a difference between the internal pressure of the wick and the flow resistance of the working fluid having an at least specified value.

13. The electronic device of claim 11, wherein the at least specified value is a positive integer.

14. The electronic device of claim 11, wherein the heat-dissipating structure is configured such that the internal pressure of the wick and the flow resistance of the working fluid are changed based on a substantial length of the heat-dissipating structure facing the first direction.

15. The electronic device of claim 14, wherein the substantial length of the heat-dissipating structure includes a curved part of the heat-dissipating structure.
